(19) United States
(12) Patent Application Publication
(10) Pub. No.: US 2016/0035605 A1
(43) Pub. Date: Feb. 4, 2016

(54) Support Structure, Method of Controlling the Temperature Of The Same, and Apparatuses Including the Same

(71) Applicant: ASML NETHERLANDS B.V., Veldhoven (NL)

(72) Inventors: Roger Wilhelmus Antonius Henricus SCHMITZ, Helmond (NL); Sander Catharina Reinier DERKS, Budel (NL); Leon Martin LEVASIER, Hedel (NL)

(73) Assignee: ASML Netherlands B.V., Veldhoven (NL)

(21) Appl. No.: 14/775,237

(22) PCT Filed: Mar. 17, 2014
(86) PCT No.: PCT/EP2014/055326

§ 371 Date: Sep. 11, 2015

Related U.S. Application Data
(60) Provisional application No. 61/810,052, filed on Apr. 9, 2013.

(51) Int. Cl. H01L 21/67; G05D 23/19; G05B 15/02; H01L 21/687; H01L 21/66

(52) U.S. Cl. CPC H01L 21/67248; H01L 21/67069; H01L 21/68785; H01L 22/12; G05B 15/02; G05D 23/1917

(57) ABSTRACT

Disclosed are support structure apparatuses for holding a substrate or patterning device, for example in a lithographic apparatus, and apparatuses comprising such support structure apparatuses. The support structure apparatus comprises a temperature regulation system for controlling the temperature of the support structure and one or more temperature sensors located on the periphery of said support structure being operable to measure the temperature of the support structure at said periphery. The temperature regulation system may be operable to calculate an average temperature of the substrate holder from temperature values measured by said temperature sensors and position dependent correlation factors, which depend upon the position of an applied heat load on a substrate or patterning device mounted upon the support structure.

### CROSS-REFERENCE TO RELATED APPLICATIONS

This application claims the benefit of U.S. provisional application 60/810,052, which was filed on 9 Apr. 2013, and which is incorporated herein in its entirety by reference.

### FIELD

The present invention relates to a support structure for holding a substrate or patterning device in processes such as semiconductor production or inspection. Such processes may include for example EUV lithographic processes.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured. A theoretical estimate of the limits of pattern printing can be given by the Rayleigh criterion for resolution as shown in equation (1):

$$C D = {k}_{1} * \frac{λ}{N A} \qquad ( 1 )$$

where λ is the wavelength of the radiation used, NA is the numerical aperture of the projection system used to print the pattern, k1 is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 5-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

EUV radiation may be produced using a plasma. A radiation source apparatus for producing EUV radiation may include a laser for exciting a fuel to provide the plasma, and a source collector apparatus for containing the plasma. The plasma may be created, for example, by directing a laser beam at a fuel, such as particles of a suitable material (e.g. tin), or a stream of a suitable gas or vapor, such as Xe gas or Li vapor. The resulting plasma emits output radiation, e.g., EUV radiation, which is collected using a radiation collector. The radiation collector may be a mirrored normal incidence radiation collector, which receives the radiation and focuses the radiation into a beam. The radiation source apparatus may include an enclosing structure or chamber arranged to provide a vacuum environment to support the plasma. Such a radiation system is typically termed a laser produced plasma (LPP) source.

Heat loads on the substrate and substrate support, or reticle and reticle support, may result in distortion of both the substrate/reticle and the support structure, which can result in overlay errors. To counter this, temperature regulation (e.g. cooling) may be provided, for example, by passing a heat exchange fluid through the support structure, so as to transfer heat away from it.

It is desirable to improve on such temperature regulation arrangements for a support structure, such as a substrate support.

### SUMMARY

The invention in a first aspect provides a support structure apparatus comprising: a support structure for holding a substrate or patterning device; a temperature regulation system for controlling the temperature of the support structure; and one or more temperature sensors located on the periphery of said support structure and being operable to measure the temperature of the support structure at said periphery, wherein said temperature regulation system is operable to calculate an average temperature of the support structure from temperature values measured by said temperature sensors.

The invention in a further aspect provides for a method of controlling the temperature of the support structure comprising: measuring the temperature of a support structure at one or more points on the periphery of the support structure; multiplying each measured temperature with a position dependent correlation factor, appropriate to the position of an applied heat load on a substrate or patterning device mounted upon the support structure; and summing the resultant values from the above multiplying step so as to obtain an average temperature of the support structure.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

Embodiments of the invention are described, by way of example only, with reference to the accompanying drawings, in which:

FIG. 1 depicts schematically a lithographic apparatus having reflective projection optics;

FIG. 2 is a more detailed view of the apparatus of FIG. 1 including a first example of an LPP radiation source;

FIG. 3 shows an alternative configuration for the LPP radiation source in the apparatus of FIGS. 1 and 2;

FIG. 4 shows a substrate and substrate holder arrangement comprising a heat exchange fluid temperature regulation arrangement;

FIG. 5 shows part of the arrangement of FIG. 4 before (top) and after (bottom) a heat load is applied;

FIG. 6 is a graph of substrate holder temperature (vertical axis) against time (horizontal axis) illustrating the issue of insufficient thermal recovery of the substrate holder; and

FIG. 7 shows a substrate and substrate holder arrangement according to an embodiment of the invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION OF EXEMPLARY EMBODIMENTS

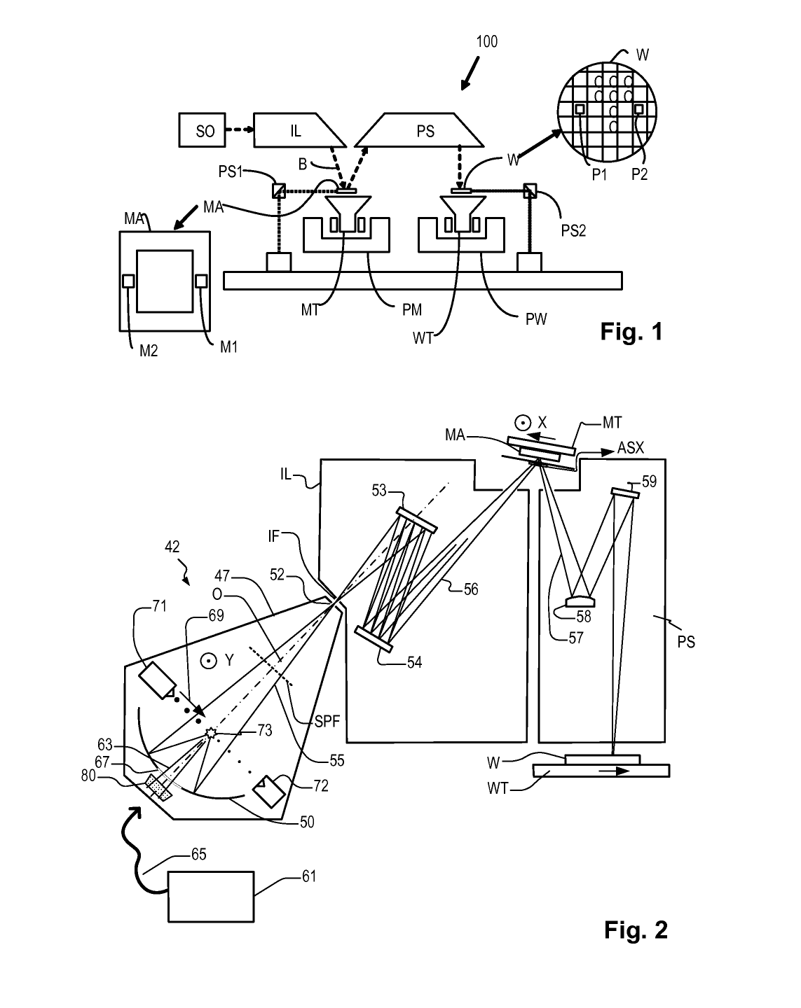

FIG. 1 schematically depicts a lithographic apparatus 100 including a source module SO according to one embodiment of the invention. The apparatus comprises:

an illumination system (illuminator) IL configured to condition a radiation beam B (e.g. EUV radiation).

a support structure (e.g. a mask table) MT constructed to support a patterning device (e.g. a mask or a reticle) MA and connected to a first positioner PM configured to accurately position the patterning device;

a substrate table (e.g. a wafer table) WT constructed to hold a substrate (e.g. a resist-coated wafer) W and connected to a second positioner PW configured to accurately position the substrate; and

a projection system (e.g. a reflective projection system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable minor arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small minors, each of which can be individually tilted so as to reflect an incoming radiation beam in different directions. The tilted mirrors impart a pattern in a radiation beam which is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the apparatus is of a reflective type (e.g. employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultra violet radiation beam from the source module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source module. The laser and the source module may be separate entities, for example when a CO2 laser is used to provide the laser beam for fuel excitation.

In such cases, the laser is not considered to form part of the lithographic apparatus and the radiation beam is passed from the laser to the source module with the aid of a beam delivery system comprising, for example, suitable directing mirrors and/or a beam expander. In other cases the source may be an integral part of the source module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as a-outer and a-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using mask alignment marks M1, M2 and substrate alignment marks P1, P2.

The depicted apparatus could be used in at least one of the following modes:
1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.
2. In scan mode, the support structure (e.g. mask table) MT and the substrate table WT are scanned synchronously while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.
3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable minor array of a type as referred to above.

Combinations and/or variations on the above described modes of use or entirely different modes of use may also be employed.

FIG. 2 shows an embodiment of the lithographic apparatus in more detail, including a radiation system 42, the illumination system IL, and the projection system PS. The radiation system 42 as shown in FIG. 2 is of the type that uses a laser-produced plasma as a radiation source. EUV radiation may be produced by a gas or vapor, for example Xe gas, Li vapor or Sn vapor in which a very hot plasma is created to emit radiation in the EUV range of the electromagnetic spectrum. The very hot plasma is created by causing an at least partially ionized plasma by, for example, optical excitation using CO2 laser light. Partial pressures of, for example, 10 Pa of Xe, Li, Sn vapor or any other suitable gas or vapor may be required for efficient generation of the radiation. In an embodiment, Sn is used to create the plasma in order to emit the radiation in the EUV range.

The radiation system 42 embodies the function of source SO in the apparatus of FIG. 1. Radiation system 42 comprises a source chamber 47, in this embodiment not only substantially enclosing a source of EUV radiation, but also collector 50 which, in the example of FIG. 2, is a normal-incidence collector, for instance a multi-layer minor.

As part of an LPP radiation source, a laser system 61 is constructed and arranged to provide a laser beam 63 which is delivered by a beam delivering system 65 through an aperture 67 provided in the collector 50. Also, the radiation system includes a target material 69, such as Sn or Xe, which is supplied by target material supply 71. The beam delivering system 65, in this embodiment, is arranged to establish a beam path focused substantially upon a desired plasma formation position 73.

In operation, the target material 69, which may also be referred to as fuel, is supplied by the target material supply 71 in the form of droplets. When such a droplet of the target material 69 reaches the plasma formation position 73, the laser beam 63 impinges on the droplet and an EUV radiation-emitting plasma forms inside the source chamber 47. In the case of a pulsed laser, this involves timing the pulse of laser radiation to coincide with the passage of the droplet through the position 73. As mentioned, the fuel may be for example xenon (Xe), tin (Sn) or lithium (Li). These create a highly ionized plasma with electron temperatures of several 10's of eV. Higher energy EUV radiation may be generated with other fuel materials, for example Tb and Gd. The energetic radiation generated during de-excitation and recombination of these ions includes the wanted EUV which is emitted from the plasma at position 73. The plasma formation position 73 and the aperture 52 are located at first and second focal points of collector 50, respectively and the EUV radiation is focused by the normal-incidence collector mirror 50 onto the intermediate focus point IF.

The beam of radiation emanating from the source chamber 47 traverses the illumination system IL via so-called normal incidence reflectors 53, 54, as indicated in FIG. 2 by the radiation beam 56. The normal incidence reflectors direct the beam 56 onto a patterning device (e.g. reticle or mask) positioned on a support (e.g. reticle or mask table) MT. A patterned beam 57 is formed, which is imaged by projection system PS via reflective elements 58, 59 onto a substrate carried by wafer stage or substrate table WT. More elements than shown may generally be present in illumination system IL and projection system PS. For example there may be one, two, three, four or even more reflective elements present than the two elements 58 and 59 shown in FIG. 2. Radiation collectors similar to radiation collector 50 are known from the prior art.

As the skilled reader will know, reference axes X, Y and Z may be defined for measuring and describing the geometry and behavior of the apparatus, its various components, and the radiation beams 55, 56, 57. At each part of the apparatus, a local reference frame of X, Y and Z axes may be defined. The Z axis broadly coincides with the direction of optical axis O at a given point in the system, and is generally normal to the plane of a patterning device (reticle) MA and normal to the plane of substrate W. In the source module (apparatus) 42, the X axis coincides broadly with the direction of fuel stream (69, described below), while the Y axis is orthogonal to that, pointing out of the page as indicated. On the other hand, in the vicinity of the support structure MT that holds the reticle MA, the X axis is generally transverse to a scanning direction aligned with the Y axis. For convenience, in this area of the schematic diagram FIG. 2, the X axis points out of the page, again as marked. These designations are conventional in the art and will be adopted herein for convenience. In principle, any reference frame can be chosen to describe the apparatus and its behavior.

In addition to the wanted EUV radiation, the plasma produces other wavelengths of radiation, for example in the visible, UV and DUV range. There is also IR radiation present from the laser beam 63. The non-EUV wavelengths are not wanted in the illumination system IL and projection system PS and various measures may be deployed to block the non-EUV radiation. As schematically depicted in FIG. 2, a transmissive SPF may be applied upstream of the virtual source point IF. Alternatively or in addition to such a filter, filtering functions can be integrated into other optics. For example a diffractive filter can be integrated in collector 50 and/or mirrors 53, 54 etc., by provision of a grating structure tuned to divert the longer, IR radiation away from the virtual source point IF. Filters for IR, DUV and other unwanted wavelengths may thus be provided at one or more locations along the paths of beams 55, 56, 57, within source module (radiation system 42), the illumination system IL and/or projection system PS.

To deliver the fuel, which for example is liquid tin, a droplet generator or target material supply 71 is arranged within the source chamber 47, to fire a stream of droplets towards the plasma formation position 73. In operation, laser beam 63 may be delivered in a synchronism with the operation of target material supply 71, to deliver impulses of radiation to turn each fuel droplet into a plasma. The frequency of delivery of droplets may be several kilohertz, or even several tens or hundreds of kilohertz. In practice, laser beam 63 may be delivered by a laser system 61 in at least two pulses: a pre pulse PP with limited energy is delivered to the droplet before it reaches the plasma location, in order to vaporize the fuel material into a small cloud, and then a main pulse MP of laser energy is delivered to the cloud at the desired location, to generate the plasma. In a typical example, the diameter of the plasma is about 2-3 mm A trap 72 is provided on the opposite side of the enclosing structure 47, to capture fuel that is not, for whatever reason, turned into plasma.

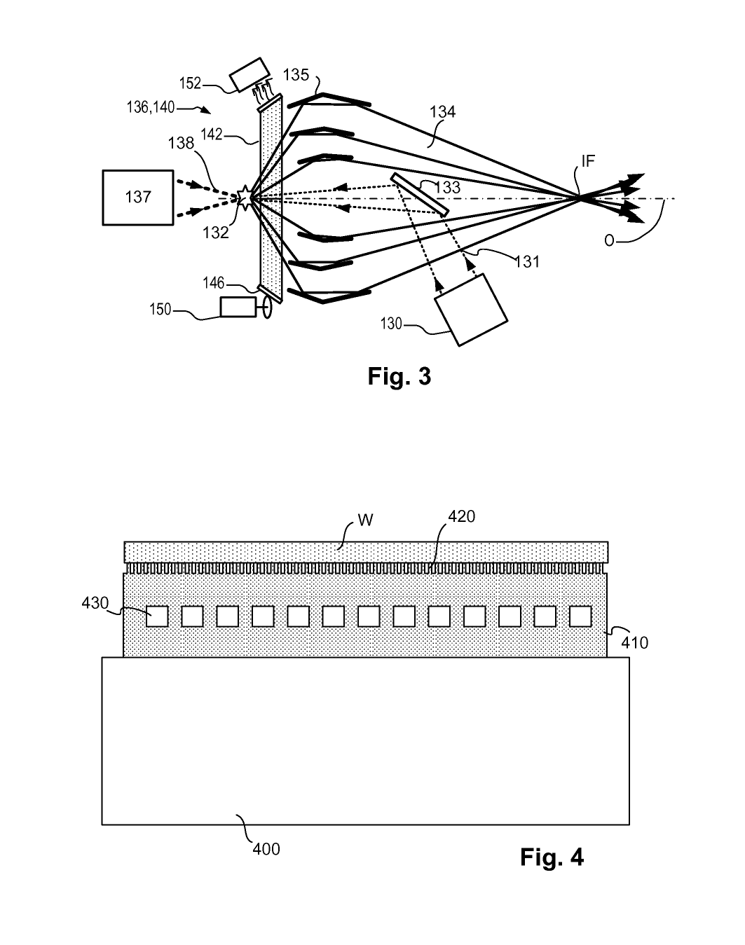

FIG. 3 shows an alternative LPP source arrangement which may be used in place of that illustrated in FIG. 2. A main difference is that the main pulse laser beam is directed onto the fuel droplet from the direction of the intermediate focus point IF, such that the collected EUV radiation is that which is emitted generally in the direction from which the main laser pulse was received.

FIG. 3 shows the main laser beam delivery system 130 emitting a main pulse beam 131 delivered to a plasma formation position 132. At least one optical element of the beam delivery system, in this case a folding mirror 133 is located on the optical axis between plasma position 132 and the intermediate focus. (The term “folding” here refers to folding of the beam, not folding of the minor.) The EUV radiation 134 emitted by a plasma at position 132, or at least the major portion that is not directed back along the optical axis 0 into the folding mirror 133 is collected by a grazing incidence collector 135. This type of collector is known already in the art, but is generally used in discharge produced plasma (DPP) sources, not LPP sources. Also shown is a debris trap 136. A pre-pulse laser 137 is provided to deliver a pre-pulse laser beam 138 to fuel droplets. In this example, the pre-pulse energy is delivered to the side of the fuel droplet that faces away from the intermediate focus point IF. It should be understood that the elements shown in this schematic diagram are not to scale.

FIG. 4 shows a substrate stage 400. The substrate stage 400 includes a first substrate holder 410, the substrate holder 410 comprising, for example, a chuck and wafer table assembly (This wafer table may be wafer table WT depicted in FIGS. 1 and 2). In FIG. 4, the chuck and substrate table are schematically shown as being one part (the substrate holder 410), however, generally, they may be separate parts. As is shown in FIG. 4, a substrate W can be held by the substrate holder 410, for example a substrate W which is to be illuminated by a projection beam, such that a pattern from a patterning structure can be transferred to the substrate during use. Such a projection beam and patterning structure are not shown in FIG. 4, but they can be configured, for example, as described above regarding FIGS. 1 and 2, as will be clear to the person skilled in the art.

The substrate stage 400 and/or substrate holder 410 may be configured in various ways. For example, a support side of the substrate holder 410, that is the support side which faces the substrate W during use, may comprise support protrusions or burls 420. Such protrusions can contact a surface of the substrate W mechanically during use.

The substrate holder 410 includes a temperature regulation system utilizing a heat exchange fluid, such as a cooling water, which is configured to supply the heat exchange fluid to and/or through the substrate holder 410. For example, the substrate holder 410 may include channels 430, which can be fed by cooling water during use to cool the substrate holder 410. In other applications it may be desirable to raise the temperature of the substrate holder, in which case the temperature regulation system may operate to heat the substrate holder.

At present, the source power output of EUV systems is low and therefore the heat reaching the substrate is small. Therefore, it is possible to obtain acceptable performance by thermally controlling the substrate holder temperature using temperature sensors in the water supply for monitoring of the substrate holder 410 temperature. These sensors are often located at the outlet of the water channel inside the clamp. However, as source power increases, and therefore heat load on the substrate W and substrate holder also increases, such an arrangement will no longer be able to react sufficiently quickly for acceptable control of the substrate holder 410 temperature.

In general there are two main issues:

Heat loads deform the substrate W and substrate holder 410 during exposure of the substrate, resulting in overlay errors; and

Insufficient thermal recovery of the substrate holder 410 following exposure of a previous substrate W, also resulting in overlay errors.

### Heat Loads Deforming Substrate and Substrate Holder

A typical EUV source produces EUV, DUV (deep ultraviolet) and IR (infra red) heat loads on the substrate and substrate holder. The IR heat load on the substrate holder depends upon the reflectivity and transmissivity of the substrate. For example, while about 100% of the EUV load falls on the substrate during exposure, typically only about 25% of the IR load falls on the substrate. The remaining 75% of the IR load is on the substrate holder. These heat loads are envisaged to reach 0.44W (for a 250W source).

Uncontrolled, the heat loads result in a mechanical deformation of substrate and substrate holder, thereby causing an overlay error. The mechanical deformation is caused partly by substrate expansion and partly by substrate holder expension. It should be noted that there is a difference in the coeffcient of thermal expansion between the silicon (Si) substrate and the silicon carbide (SiSiC) substrate holder which results in the substrate expanding by more than the substrate holder, although this is partly suppressed by the stiffness of the burls on top of the substrate holder.

This global expansion can lead to overlay errors up to 2 nm, of which about a third may be attributable to the substrate holder deformation and about two-thirds may be attributable to deformation of the substrate itself. This is approximate and will depend on the actual heat load falling on the substrate holder and falling on the substrate, and also on the thermal coupling between substrate holder and substrate (the better the coupling the higher the contribution of the substrate holder to the total grid deformation). The previously described temperature regulation system, which monitors the substrate holder temperature by monitoring the water supply temperature, is too slow to compensate for this in sufficient time.

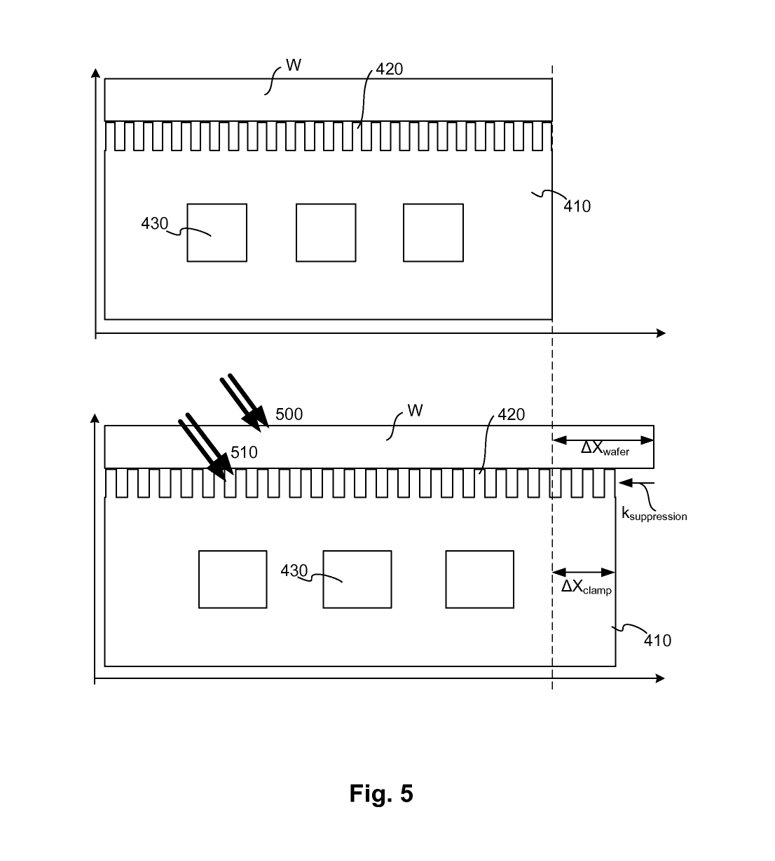

FIG. 5 shows part (one end) of the arrangement of FIG. 4 before (top) and after (bottom) a heat load 500, 510 is applied. Heat load 500 is the heat load on the substrate which is resultant from EUV/DUV and IR radiation and gas flow from a dynamic gas lock mechanism (which results in a gas flow impinging onto the substrate). Heat load 510 is the heat load on the substrate holder, which is resultant from IR radiation transmitted through the substrate. It can be shown that the raw grid deformation (RGD) can be approximated to (first order approximation):

$$R G D \approx Δ {x}_{clamp} + \frac{Δ {x}_{wafer} - Δ {x}_{clamp}}{{k}_{sup p ression}}$$

Where Δx_{wafer} is the difference in the substrate diameter before and after application of the heat load, Δx_{ciamp} is the difference in the substrate holder size before and after application of the heat load and kₛᵤₚₚᵣₑₛₛᵢₒₙ is the effect of the stiffness of the substrate stage and substrate holder system on the substrate expansion. Focus-Exposure Modelling can be used to more accurately calculate the RGD.

### Insufficient Thermal Recovery of the Substrate Holder

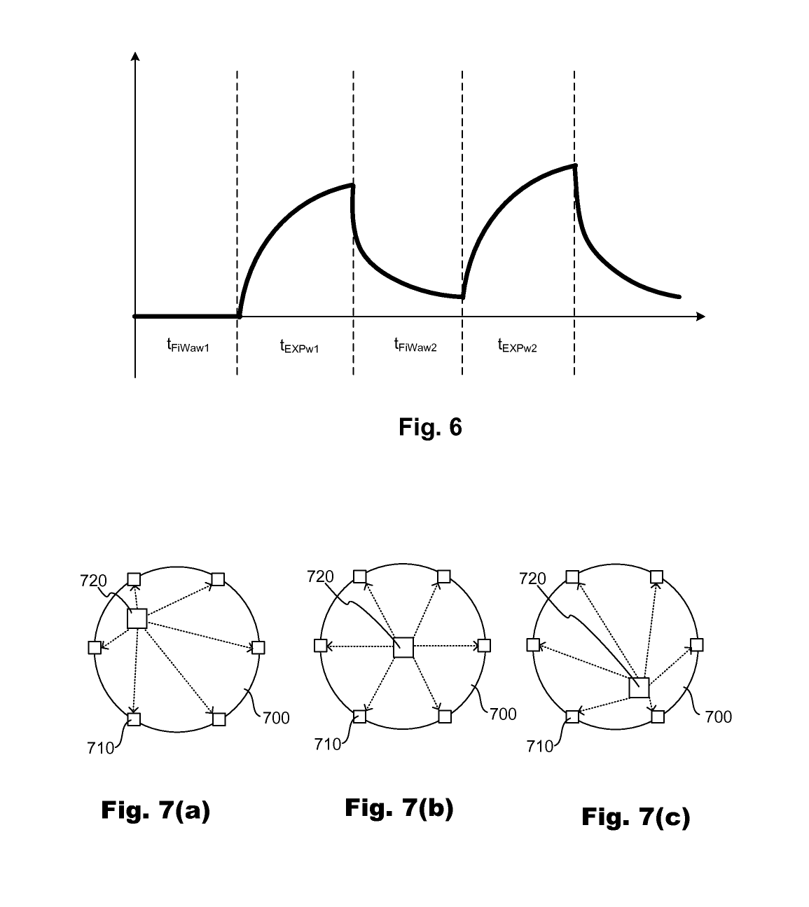

FIG. 6 shows schematically the problem with substrate to substrate effects caused by thermal history, should sensor in water supply techniques be used with higher source powers. It shows a plot of the substrate holder temperature (vertical axis) against time (horizontal axis). There are four time periods labeled: t_{FiWaw1} is the time for fine alignment of a first substrate, t_{Expw1} is the exposure time of the first substrate, t_{FiWaw2} is the time for fine alignment of a second substrate and t_{Expw2} is the exposure time of the second substrate. It can be seen that not all the heat gained by the substrate holder during time t_{Expw1} is removed during time t_{FiWaw2}. As a result, the temperature at the beginning of the period t_{Expw2} is higher than the temperature at the beginning of the period t_{Expw1}. This can result in direct overlay errors up to 0.8 nm.

Providing temperature sensors on the substrate holder for direct measurement of the substrate holder temperature would allow for improved control of the temperature of the substrate holder and substrate, as it would allow for a much faster response compared to a temperature sensor directly measuring the water supply temperature. However, for current electrostatic clamp (ESC) type substrate holders, it is very difficult to manufacture temperature sensors in the body of the substrate holder (SiSiC body).

It is therefore proposed to place temperature sensors on the edge of the substrate holder. This is easier than placing sensors in the substrate holder body. In this case, a correlation calculation should be performed so as to calculate the average substrate holder temperature from the temperature values measured by the sensors at the substrate holder edge, thereby providing the correct input to the temperature regulation system controller.

FIG. 7 illustrates such an arrangement. It shows a substrate holder 700 (with substrate mounted) and six sensors 710 around the substrate holder periphery. It should be appreciated that the number and actual arrangement of the sensors is shown here purely for illustration, and there may be more or fewer than six sensors, and the sensors may be arranged differently.

A correlation calculation is performed using position dependent correlation factors. This position dependency refers to the position where the disturbance load is applied (i.e. expose load) and will be different for substrate holders having other physical layouts. FIGS. 7(a) to 7(c) each show a heat load 720 being applied at a different location. In FIG. 7(a) the heat load is applied at coordinates X1, Y1, in FIG. 7(b) the heat load is applied at coordinates X2, Y2 and in FIG. 7(c) the heat load is applied at coordinates X3, Y3.

The readout of the individual sensors is used to calculate an average substrate holder temperature. This can be performed using the equation:

dTₐᵥ(t)=Σᵢ₌₁ⁿa(x, y)ₜ*dTedge(t)ᵢ

where dTₐᵥ is the change in average temperature, i is the sensor number (n=6 in the example shown), dTedge(t)ᵢ is the temperature measured directly by each sensor at the substrate holder edge and a(x,y)ᵢ is the position dependent correlation factor. The correlation factors can be defined by experiment or estimated by means of Focus-Exposure Modelling analysis. Also, a combination of these methods can be used. The correlation factors should be determined such that they will be the same for all possible routing and timing sequences for imaging a substrate; so that it is not necessary to determine a new set of correlation factors when imaging using different routings and timings. In this way the arrangement is robust to timing differences during exposure.

While the above describes a substrate support in particular, it should be appreciated that the inventive concept is also applicable to a patterning device (i.e. mask or reticle) support. However, patterning device supports presently tend to be made of low conductivity material, which means that the sensors on the edge will not be able to react as quickly to the temperature disturbance. Therefore it may be preferable that the patterning device support also be made of a higher conductivity material if the concepts described herein are to be applied thereto.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers. The concepts described herein may also be applicable to tools such as reticle inspection tools or plasma etchers and deposition apparatuses.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, certain aspects of the invention (e.g. those relating to the correlation calculations) may take the form of a computer program containing one or more sequences of machine-readable instructions describing a method as disclosed above, or a data storage medium (e.g. semiconductor memory, magnetic or optical disk) having such a computer program stored therein. The descriptions above are intended to be illustrative, not limiting. Thus it will be apparent to one skilled in the art that modifications may be made to the invention as described without departing from the scope of the claims set out below.

1. A support structure apparatus comprising:
a support structure for holding a substrate or patterning device;
a temperature regulation system for controlling the temperature of the support structure; and one or more temperature sensors located on the periphery of said support structure and being operable to measure the temperature of the support structure at said periphery,
wherein said temperature regulation system is operable to calculate an average temperature of the support structure from temperature values measured by said one or more temperature sensors, and
wherein said average temperature of the su ort structure is calculated usin position dependent correlation factors, which are dependent on a position of an applied heat load on a substrate or patterning device mounted upon the support structure.

2. A support structure apparatus as claimed in claim 1 wherein there are a plurality of temperature sensors located on the periphery of said support structure and wherein said plurality of temperature sensors are evenly spaced around the periphery of said support structure.

3. (canceled)

4. The support structure apparatus as claimed in claim 1 wherein said average temperature of the support structure is calculated by summing together each temperature value as measured by each temperature sensor multiplied in each case by the appropriate position dependent correlation factor.

5. The support structure apparatus as claimed in claim 4 wherein the correlation factors have been predetermined by experiment, at least in part.

6. The support structure apparatus as claimed in claim 4 wherein the correlation factors have been predetermined by means of Focus-Exposure Modeling analysis, at least in part.

7. (canceled)

8. The support structure apparatus as claimed in claim 1 wherein said temperature regulation system is operable to use said calculated average temperature as a feedback input for controlling the temperature of said support structure.

9. The support structure apparatus as claimed in claim 1 wherein each of said sensors is operable to directly measure the temperature of the support structure at its location on said periphery of the support structure.

10. An apparatus for use in a semiconductor production process comprising the support structure apparatus comprising:
a support structure for holding a substrate or patterning device;
a temperature regulation system for controlling the temperature of the support structure; and one or more temperature sensors located on the periphery of said support structure and being operable to measure the temperature of the support structure at said periphery,
wherein said temperature regulation system is operable to calculate an average temperature of the support structure from temperature values measured b said one or more temperature sensors and
wherein said average temperature of the support structure is calculated using position dependent correlation factors, which are dependent on a position of an applied heat load on a substrate or patterning device mounted upon the support structure.

11. The [[An]] apparatus as claimed in claim 10, comprising:
a lithographic apparatus being configured to generate a beam of radiation; and
a projection system within a projection chamber and configured to project the beam of radiation onto a target portion of a substrate.

12. The apparatus as claimed in claim 10, comprising an inspection apparatus for inspection of a substrate or patterning device held by said support structure.

13. The apparatus as claimed in claim 10, comprising a plasma etching and deposition device.

14. A method of controlling the temperature of a support structure comprising:
measuring the temperature of the support structure at one or more points on the periphery of the support structure;
multiplying each measured temperature with a position dependent correlation factor, appropriate to the position of an applied heat load on a substrate or patterning device mounted upon the support structure; and
summing the resultant values from the above multiplying step so as to obtain an average temperature of the support structure.

15. The method of claim 14 comprising using said calculated average temperature as a feedback input for controlling the temperature of said support structure.

16. The method of claim 14 comprising the initial step of determining the correlation factors.

17. The method of claim 16 wherein the correlation factors are determined by experiment, at least in part.

18. The method of claim 16 wherein the correlation factors are determined by means of Focus-Exposure Modelling analysis, at least in part.

19. (canceled)
